(19) United States
(12) Patent Application Publication
(10) Pub. No.: US 2011/0017257 A1
(43) Pub. Date: Jan. 27, 2011

(54) MULTI-JUNCTION SOLAR MODULE AND METHOD FOR CURRENT MATCHING BETWEEN A PLURALITY OF FIRST PHOTOVOLTAIC DEVICES AND SECOND PHOTOVOLTAIC DEVICES

(75) Inventors: HOWARD W.H. LEE, Saratoga, CA (US); CHESTER A. FARRIS, III, Yorba Linda, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: STION CORPORATION, San Jose, CA (US)

(21) Appl. No.: 12/512,978

(22) Filed: Jul. 30, 2009

Related U.S. Application Data
(60) Provisional application No. 61/092,383, filed on Aug. 27, 2008.

(51) Int. Cl. H01L 31/042; H01L 31/18

(52) U.S. Cl. 136/244; 438/67; 257/E21.499

(57) ABSTRACT

A multi-junction solar module apparatus. The apparatus has a substrate member. The apparatus has a plurality of first photovoltaic devices arranged in a first spatial configuration, which is preferably disposed on a first planar region. In a specific embodiment, the plurality of first photovoltaic devices are numbered from 1 through N, where N is an integer greater than 1. Each of the plurality of first solar cells has a first bandgap characteristic. The apparatus has a plurality of second photovoltaic devices arranged in a second spatial configuration, which is preferably disposed in a second planar region. The plurality of second photovoltaic devices are numbered from 1 through M, where M is an integer greater than 1. In a preferred embodiment, N is not equal to M. Each of the second solar cells has a second band gap characteristic. In a specific embodiment, a first connector interconnects the plurality of first solar cells in a serial configuration. The first connector has a first terminal end and a second terminal end. A second connector interconnects the plurality of second solar cells in a serial configuration. The second connector has a first terminal end and a second terminal end. In a specific embodiment, a third connector connecting the second terminal end of the first connector and the first terminal end of the second connector. In a specific embodiment, a Vss node is coupled to the first terminal end of the first connector. In a specific embodiment, a Vdd node is coupled to the second terminal end of the second connector. In a preferred embodiment, N and M are selected to match a first current through the plurality of first solar cells and a second current through the plurality of second solar cells.

### CROSS-REFERENCES TO RELATED APPLICATIONS

This application claims priority to U.S. Provisional Patent Application No. 61/092,383, filed Aug. 27, 2008, entitled “MULTI-JUNCTION SOLAR MODULE AND METHOD FOR CURRENT MATCHING BETWEEN A PLURALITY OF FIRST PHOTOVOLTAIC DEVICES AND SECOND PHOTOVOLTAIC DEVICES” by inventors HOWARD W. H. LEE et al. This application is also related to U.S. patent application Ser. No. 11/748,444, filed May 14, 2007, U.S. patent application Ser. No. 11/804,019, filed May 15, 2007, and U.S. Provisional Patent Application No. 60/988,099, filed Nov. 14, 2007, all commonly assigned and incorporated by reference herein for all purposes.

### STATEMENT AS TO RIGHTS TO INVENTIONS MADE UNDER FEDERALLY SPONSORED RESEARCH OR DEVELOPMENT

Not applicable

### REFERENCE TO A “SEQUENCE LISTING,” A TABLE, OR A COMPUTER PROGRAM LISTING APPENDIX SUBMITTED ON A COMPACT DISK.

Not applicable

### BACKGROUND OF THE INVENTION

The present invention relates generally to photovoltaic materials. More particularly, the present invention provides a method and structure for manufacture of multi-junction solar module using a current matching structure and method for thin and thick film photovoltaic materials. Merely by way of example, the present method and structure have been implemented using a solar module having multiple thin film materials, but it would be recognized that the invention may have other configurations.

From the beginning of time, human beings have been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important source. Petrochemical energy includes gas and oil. Gas includes lighter forms such as butane and propane, commonly used to heat homes and serve as fuel for cooking. Gas also includes gasoline, diesel, and jet fuel, commonly used for transportation purposes. Heavier forms of petrochemicals can also be used to heat homes in some places. Unfortunately, petrochemical energy is limited and essentially fixed based upon the amount available on the planet Earth. Additionally, as more human beings begin to drive and use petrochemicals, it is becoming a rather scarce resource, which will eventually run out over time.

More recently, clean sources of energy have been desired. An example of a clean source of energy is hydroelectric power. Hydroelectric power is derived from electric generators driven by the force of water that has been held back by large dams such as the Hoover Dam in Nev. The electric power generated is used to power up a large portion of Los Angeles, Calif. Other types of clean energy include solar energy. Specific details of solar energy can be found throughout the present background and more particularly below.

Solar energy generally converts electromagnetic radiation from our sun to other useful forms of energy. These other forms of energy include thermal energy and electrical power. For electrical power applications, solar cells are often used. Although solar energy is clean and has been successful to a point, there are still many limitations before it becomes widely used throughout the world. As an example, one type of solar cell uses crystalline materials, which form from semiconductor material ingots. These crystalline materials include photo-diode devices that convert electromagnetic radiation into electrical current. Crystalline materials are often costly and difficult to make on a wide scale. Additionally, devices made from such crystalline materials have low energy conversion efficiencies. Other types of solar cells use “thin film” technology to form a thin film of photosensitive material to be used to convert electromagnetic radiation into electrical current. Similar limitations exist with the use of thin film technology in making solar cells. That is, efficiencies are often poor. Additionally, film reliability is often poor and cannot be used for extensive periods of time in conventional environmental applications. There have been attempts to form heterojunction cells using a stacked configuration. Although somewhat successful, it is often difficult to match currents between upper and lower solar cells. These and other limitations of these conventional technologies can be found throughout the present specification and more particularly below.

From the above, it is seen that improved techniques for manufacturing photovoltaic materials and resulting devices are desired.

### BRIEF SUMMARY OF THE INVENTION

According to the present invention, techniques related to photovoltaic materials are provided. More particularly, the present invention provides a method and structure for manufacture of multi-junction solar module using a current matching structure and method for thin and thick film photovoltaic materials. Merely by way of example, the present method and structure have been implemented using a solar module having multiple thin film materials, but it would be recognized that the invention may have other configurations.

In a specific embodiment, the present invention provides a multi-junction solar module apparatus. The apparatus has a substrate member, e.g., glass. The apparatus has a plurality of first photovoltaic devices arranged in a first spatial configuration, which is preferably disposed on a first planar region. In a specific embodiment, the plurality of first photovoltaic devices are numbered from 1 through N, where N is an integer greater than 1. Each of the plurality of first solar cells has a first bandgap characteristic. The apparatus has a plurality of second photovoltaic devices arranged in a second spatial configuration, which is preferably disposed in a second planar region. The plurality of second photovoltaic devices are numbered from 1 through M, where M is an integer greater than 1. In a preferred embodiment, N is not equal to M. Each of the second solar cells has a second band gap characteristic. In a specific embodiment, a first connector interconnects the plurality of first solar cells in a serial configuration. The first connector has a first terminal end and a second terminal end. A second connector interconnects the plurality of second solar cells in a serial configuration. The second connector has a first terminal end and a second terminal end. In a specific embodiment, a third connector connecting the second terminal end of the first connector and the first terminal end of the second connector. In a specific embodiment, a Vss node is coupled to the first terminal end of the first connector. In a specific embodiment, a Vdd node is coupled to the second terminal end of the second connector. In a preferred embodiment, N and M are selected to match a first current through the plurality of first solar cells and a second current through the plurality of second solar cells.

Depending upon the specific embodiment, one or more of these features may also be included. The present technique provides an easy to use process that relies upon conventional technology that is nanotechnology based. In some embodiments, the method may provide higher efficiencies in converting sunlight into electrical power using a multiple junction design and method. Depending upon the embodiment, the efficiency can be about 10 percent or 20 percent or greater. Additionally, the method provides a process that is compatible with conventional process technology without substantial modifications to conventional equipment and processes. In a specific embodiment, the present method and structure can also be provided using large scale manufacturing techniques, which reduce costs associated with the manufacture of the photovoltaic devices. In another specific embodiment, the present method and structure can also be provided using any combination of suitable single junction solar cell designs to form top and lower cells, although there can be more than two stacked cells depending upon the embodiment. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram of a connection structure for a module having a multi-junction cell according to a specific embodiment of the present invention;

FIG. 2 is a simplified diagram of further details of a connection structure for a module having a multi-junction cell according to a specific embodiment of the present invention;

FIG. 3 is a simplified side-view diagram of a connection structure for a multi-junction cell according to a specific embodiment of the present invention;

FIG. 4 is a simplified illustration of current and voltage for a module according to an embodiment of the present invention;

FIG. 5 is a simplified diagram of a connection structure for a module having a multi-junction cell according to another embodiment of the present invention;

FIG. 6 is a simplified diagram of a method of matching a plurality of first photovoltaic devices to a plurality of second photovoltaic devices in forming a solar module according to an embodiment of the present invention; and

FIGS. 7 is a simplified diagram illustrating an example of photovoltaic device that can be arranged as first, second, third, and Nth devices according to a specific embodiment of the present invention.

### DETAILED DESCRIPTION OF THE INVENTION

According to the present invention, techniques related to photovoltaic materials are provided. More particularly, the present invention provides a method and structure for manufacture of multi-junction solar module using a current matching structure and method for thin and thick film photovoltaic materials. Merely by way of example, the present method and structure have been implemented using a solar module having multiple thin film materials, but it would be recognized that the invention may have other configurations.

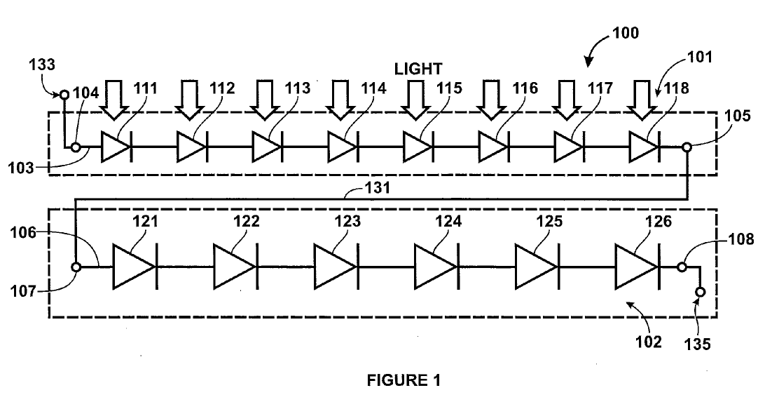

FIG. 1 is a simplified diagram of a connection structure for a module 100 having a multi-junction cell according to a specific embodiment of the present invention. This diagram is merely an example, which should not unduly limit the scope of the claims herein. One of ordinary skill in the art would recognize other variations, modifications, and alternatives. As shown, photovoltaic module 100 is formed on a substrate (not shown) and includes sub-module 101 and sub-module 102. In the embodiment shown in FIG. 1, sub-module 101 includes photovoltaic devices labeled as cells 111-118, with each cell shown schematically as a diode. Sub-module 101 also has a first connector 103 interconnecting photovoltaic devices labeled as cells 111-118 in a serial configuration. The first connector has a first terminal end 104 and a second terminal end 105. As shown in FIG. 1, sub-module 102 includes photovoltaic devices labeled as cells 121-126, with each cell shown schematically as a diode. Sub-module 102 also has a second connector 106 interconnecting solar cells 121-126 in a serial configuration. The second connector has a first terminal end 107 and a second terminal end 108. Of course, there can be other variations, modifications, and alternatives.

In the specific embodiment shown in FIG. 1, photovoltaic module 100 has a third connector 131 connecting terminal end 105 of sub-module 102 to terminal end 107 of sub-module 102. Module 101 also includes a first output node 133 connected to terminal end 104 of terminal end 104 and a second output node 135 connected to terminal end 108 of sub-module 102. As shown, sub-modules 101 and 102 are serially connected in module 100.

In a specific embodiment, cells 111-118 in sub-module 101 are made of a semiconductor material having a first bandgap and are constructed so that each cell provides substantially the same current, designated as I₁. As shown, cells 111-118 are serially connected between terminal ends 104 and 105 of sub-module 101. A terminal voltage V₁ is provided between terminal ends 104 and 105. The terminal voltage V₁ is substantially a sum of the voltages provided in each of cells 111-118.

Similarly, cells 121-126 in sub-module 102 are made of a second semiconductor material having a second bandgap and are constructed so that each cell provides substantially the same current, designated as I₂. As shown, cells 121-126 are serially connected between terminal ends 107 and 108 of sub-module 102. A terminal voltage V₂ is provided between terminal ends 107 and 108. The terminal voltage V₂ is substantially a sum of the voltages provided in each of cells 121-126.

According to an embodiment of the invention, sub-module 101 and sub-module 102 are connected in series to form module 100, as shown in FIG. 1. A first output node 133 of module 100 is coupled to the first terminal end 104 of the first connector 103, and a second output node 135 is coupled to the second terminal end 108 of the second connector 106. Additionally, a third connector 131 in module 100 connects the second terminal end 105 of the first connector and the first terminal end 107 of the second connector. In this embodiment, current I₁ in sub-module 101 and current I₂ in sub-module 102 are substantially matched. As a result, the current I provided by module 100 is substantially the same as I₁ and I₂. In this configuration module 100 now provides a terminal voltage V between the output nodes 133 and 135 which is substantially a sum of V₁ and V₂, the terminal voltages of sub-modules 101 and 102, respectively.

Depending on the embodiments, the present invention provides various methods for matching the currents in sub-modules 101 and 102. In a specific embodiment, a cell in sub-module 101, e.g. cell 111, may have different characteristics from a cell in sub-module 102, e.g. cell 121. For example, cell 111 may have a different bandgap in the absorber layer from cell 121. As another example, cell 111 may have different optical absorption properties from cell 121. For instance, they may absorb light from different parts of the optical spectrum, or they may have different optical absorption coefficients or different carrier generation efficiencies. One or more of these parameters can be used to modify the current generated in each cell. Additionally, in a specific embodiment of the invention, the cell area is selected to provide a predetermined cell current or to match currents from two different cells.

For example, if cell 111 is formed using a first material to provide a current density of i₁ per unit area and has a cell area A₁, then the cell current for cell 111 is I₁=A₁*i₁. Similarly, if cell 121 is formed using a second material to provides a current density of i₂ per unit area and has a cell area A₂, then the cell current for cell 121 is I₂=A₂*i₂. Given i₁ and i₂, cell area A₁ for cell 111 and cell area A₂ for cell 121 can then be selected such that A₁*i₁=A₂*i₂, which will substantially match the currents, i.e. I₁=I₂.

If the sub-modules have the same total area, then there can be different numbers of cells in each of the sub-modules. Accordingly, in a specific embodiment, the number of cells in each sub-module can be selected for current matching. For example, if sub-module 101 has N cells and sub-module 102 has M cells, where N and M are integers, then N and M are selected to match a first current through the plurality of first photovoltaic devices in sub-module 101 and a second current through the plurality of second photovoltaic devices in sub-module 102.

In a specific embodiment shown in FIG. 1, the areas of cells 111-118 and the areas of cells 121-126 are selected such that the currents I₁ and I₂ are matched. In this embodiment, cells in a sub-module can be optimized for performance independent of the other sub-modules. Alternatively, various other parameters can be selected for current matching purposes. For example, semiconductor materials having different bandgaps and optical absorption properties can also be used to determine the cell current. Of course, one of ordinary skill in the art would recognize many variations, modifications, and alternatives.

In a specific embodiment, module 100 can be constructed to better utilize the optical spectrum of the light source. As an example, sub-module 101 is constructed to absorb the shorter wave length portion of the sunlight spectrum, and sub-module 102 is constructed to absorb the longer wavelength portion of the sunlight. In a specific example, sub-module 101 can be made from a wider bandgap material than sub-module 102. By stacking sub-module 101 over sub-module 102, the sun light not absorbed by sub-module 101 will be absorbed by sub-module 102. Optionally, a third sub-module can be added to convert the sunlight in a portion of the spectrum not used by sub-module 101 and sub-module 102. The third sub-module can be connected to sub-module 102 in a similar way as described above.

In an alternative embodiment, each cell in module 100 can be a multi-junction cell. For example, each of cells 111-118 in sub-module 102 can include stacked multiple junctions which absorb different portions of the sunlight spectrum. The multi-junction cells can have two external terminals or three external terminals.

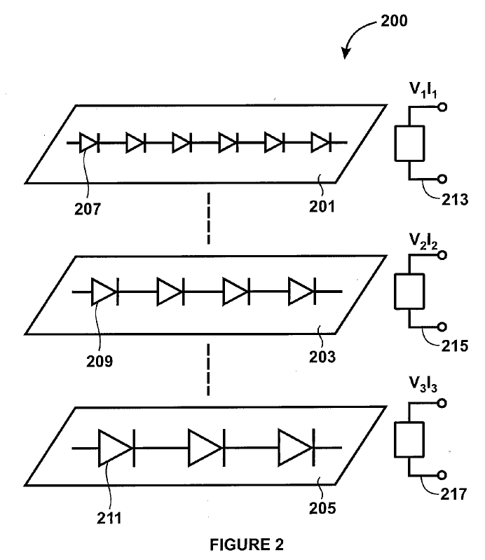

FIG. 2 is a simplified diagram of further details of a connection structure for a module having a multi-junction cell according to a specific embodiment of the present invention. This diagram is merely an example, which should not unduly limit the scope of the claims herein. One of ordinary skill in the art would recognize other variations, modifications, and alternatives. As shown, photovoltaic module 200 includes sub-modules 201, 203, and 205, etc. Each of the sub-modules includes multiple solar cells connected in series. For example, sub-module 201 includes multiple solar cells such as 207. Sub-module 201 is shown schematically as device 213, which is characterized by voltage V₁ and current I₁. Similarly, sub-module 203 includes multiple solar cells such as 209 connected serially. Sub-module 203 is shown schematically as device 215, which is characterized by voltage V₂ and current I₂. Additionally, sub-module 205 includes multiple solar cells such as 211 serially connected. Sub-module 202 is shown schematically as device 217, which is characterized by voltage V₃ and current I₃.

In a specific embodiment, sub-modules 201, 203, 205, etc., can be configured according to the method described above in connection with FIG. 1. For example, sub-modules 201, 203, and 205, etc., are stacked, and each can be constructed to absorb and convert light energies from a different portion of the sunlight spectrum. In the serial combination, the currents are matched, such that I₁=I₂=I₃. In a specific embodiment, the device areas are selected to match the currents. Of course, there are many variations, modifications, and alternatives.

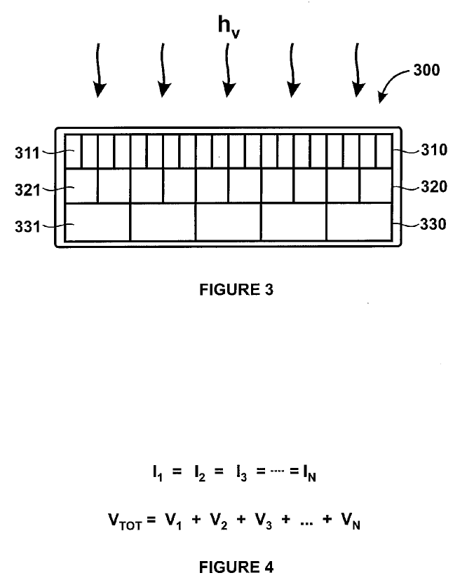

FIG. 3 is a simplified side-view diagram of a connection structure for a multi-junction module according to a specific embodiment of the present invention. This diagram is merely an example, which should not unduly limit the scope of the claims herein. One of ordinary skill in the art would recognize other variations, modifications, and alternatives. As shown, multi-junction module 300 includes sub-modules such as 310, 320, and 330, etc. Each of the sub-modules includes a number of solar cells. For example, sub-module 310 includes cells such as 311, sub-module 320 includes cells such as 321, and sub-module 330 includes cells such as 331, etc. Within each sub-module, the cells are connected serially, and the current in each cell are matched. The current for each sub-module, e.g. current I₁ for sub-module 310, current I₂ for sub-module 320, and current I₃ for sub-module 330, etc, are also matched. Accordingly, I₁=I₂=I₃. Let V₁, V₂, and V₃, etc., represent the terminal voltage of sub-modules 310, 320, and 330, etc., respectively. Then the terminal voltage of module 300, V_{TOT}, is a sum of the sub-modules. In other words, V_{TOT}=V₁+V₂+V₃.

FIG. 4 is a simplified illustration of current and voltage for a module according to an embodiment of the present invention. This diagram is merely an example, which should not unduly limit the scope of the claims herein. One of ordinary skill in the art would recognize other variations, modifications, and alternatives. As shown, FIG. 4 includes a simplified description of current and voltage relationships between N sub-modules in a module. Let the currents for modules 1, 2, 3, . . . , and N be I₁, I₂, I₃, . . . and I_{N}, respectively, and the corresponding voltages for modules 1, 2, 3, . . . , and N be V₁, V₂, V₃, . . . , and V_{N}, respectively. Then all the currents are matched, and the terminal voltage of the module V_{TOT} is the sum of the voltages for all the sub-modules, as shown in FIG. 4.

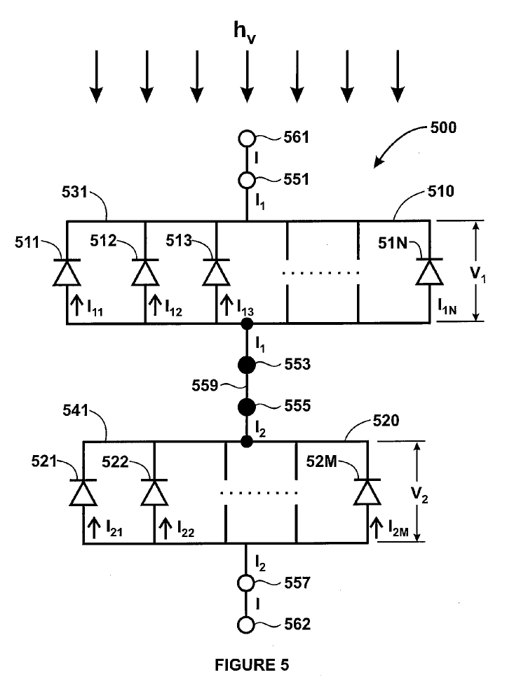

FIG. 5 is a simplified diagram of a connection structure for a module 500 having a multi-junction cell according to another embodiment of the present invention. This diagram is merely an example, which should not unduly limit the scope of the claims herein. One of ordinary skill-in-the-art would recognize other variations, modifications, and alternatives. As shown, solar module 500 is formed on a substrate (not shown) and includes sub-module 510 and sub-module 520. In the specific embodiment shown in FIG. 5, sub-module 510 includes N photovoltaic devices labeled as cells 511, 512, . . . , 51N, where N is an integer. Each of the N photovoltaic devices is shown schematically as a diode. Sub-module 510 also has a first connector 531 interconnecting photovoltaic devices 511-51N in a parallel configuration. The first connector 531 has a first terminal end 551 and a second terminal end 553. As shown in FIG. 5, sub-module 520 includes M photovoltaic devices labeled as cells 521-52M, where M is an integer. Again, each of the photovoltaic devices is shown schematically as a diode. Sub-module 520 also has a second connector 541 interconnecting solar cells 521-52M in a parallel configuration. The second connector 541 has a first terminal end 555 and a second terminal end 557.

In the specific embodiment shown in FIG. 5, module 500 has a third connector 559 connecting terminal end 553 of sub-module 510 to terminal end 555 of sub-module 520. Module 100 also includes a first output node 561 connected to terminal end 551 of sub-module 510 and a second output node 562 connected to terminal end 557 of sub-module 520. As shown, sub-modules 510 and 520 are serially connected in module 500.

In a specific embodiment, cells 511-51N in sub-module 510 are made of a semiconductor material having a first bandgap and a first device area. Cells 511-51N provide currents I₁₁-I_{1N}, respectively. The sum of currents I₁₁-I_{1N} is designated as I₁. As shown, cells 511-5IN are connected in parallel between terminal ends 551 and 553 of sub-module 510. A terminal voltage V₁ is provided between terminal ends 551 and 553.

Similarly, cells 521-52M in sub-module 520 are made of a second semiconductor material having a second bandgap and a second device area. Cells 521-52M provide currents I₂₁-I_{2M}, respectively. The sum of currents I₂₁-I_{2M} is designated as I₂. As shown, cells 521-52M are connected in parallel between terminal ends 555 and 557 of sub-module 520. A terminal voltage V₂ is provided between terminal ends 555 and 557.

According to an embodiment of the invention, sub-module 510 and sub-module 520 are connected in series to form module 500, as shown in FIG. 5. A first output node 561 of module 100 is coupled to the first terminal end 551 of the first connector 531, and a second output node 562 is coupled to the second terminal end 557 of the second connector 541. Additionally, a third connector 559 in module 500 connects the second terminal end 553 of the first connector and the first terminal end 555 of the second connector. In this embodiment, the total current I₁ in sub-module 510 and the total current I₂ in sub-module 520 are substantially matched. As a result, the current provided by module 500 is substantially the same as I₁ or I₂. In this configuration module 101 now provides a terminal voltage V₃ between the output nodes 561 and 562 which is substantially a sum of V₁ and V₂, the terminal voltages of sub-modules 510 and 520, respectively.

Each cell in sub-modules 510 and 520 may have different characteristics which may result in different cell currents. For example, these characteristics may include energy bandgap of the absorber layer material, optical absorption properties in different portions of the optical spectrum, and carrier generation efficiencies, etc. One or more of these parameters can be used to modify the current generated in each cell. Additionally, in a specific embodiment of the invention, the cell area is selected to provide a predetermined cell current or to match currents from two different cells.

According to a specific embodiment, the present invention provides a method for a parallel and serial combination of photovoltaic devices. In this embodiment, cells in a sub-module can be optimized for performance independent of the other sub-modules. As illustrated in FIG. 5, the current matching condition of module 500 and the terminal voltage can be expressed in the following equations.

I₁₁+I₁₂+I₁₃+ . . . +I_{1N}=I₂₁+I₂₂+ . . . +I_{2M} (1)

V=V₁+V₂ (2)

As a specific example, if each of cells 511-51N is formed using a first material to provide a current of i₁, then the total cell current for sub-module 510 is I₁=N*i₁. Similarly, if each of cells in sub-module 520 is formed using a second material to provides a current of i₂, then the total cell current for sub-module 520 is I₂=M*i₂. Sub-modules 510 and 520 can be advantageously connected in series if N and M are selected such that N*i₁=M*i₂, which will substantially match the currents, i.e. I₁=I₂.

In an embodiment, sub-module 510 is constructed to absorb the shorter wave length portion of the sunlight spectrum, and sub-module 520 is constructed to absorb the longer wavelength portion of the sunlight. In a specific example, sub-module 510 can be made from a wider bandgap material than sub-module 520. By stacking sub-module 510 over sub-module 520, the sun light not absorbed by sub-module 510 can be absorbed and converted to electric current by sub-module 520. Optionally, a third sub-module can be added to convert the sunlight in a portion of the spectrum not used by sub-module 510 and sub-module 520. The third sub-module can be connected to sub-module 520 in a similar way as described above.

In an alternative embodiment, each cell in module 500 can be a multi-junction cell. For example, each of cells 511-51N in sub-module 510 can include stacked multiple junctions which absorb different portions of the sunlight spectrum. The multi-junction cells can have two external terminals or three external terminals.

In the above discussion, each photovoltaic device in FIGS. 1, 2, and 5 is shown schematically as a diode, such as devices 111 and 121 in FIG. 1, devices 207, 209, and 211 in FIG. 2, and devices 511 and 521 in FIG. 5. Examples of photovoltaic devices can be found in U.S. patent application Ser. No. 11/748,444, filed May 14, 2007, U.S. patent application Ser. No. 11/804,019, filed May 15, 2007, and U.S. Provisional Patent Application No. 60/988,099, filed Nov. 14, 2007. All these applications are commonly assigned, and their contents are hereby incorporated by reference for all purposes.

Additionally, it is also noted that each of the photovoltaic devices in embodiments of this application can be a parallel or serial combination of photovoltaic devices, or even a parallel and serial combination of photovoltaic devices. Some of these interconnect combinations are discussed throughout this application. Various modifications or changes in light thereof will be suggested to persons skilled in the art and are to be included within the spirit and purview of this application.

According to a specific embodiment of the present invention, a method for making a multi-junction solar module device can be briefly outlined below.

1. Form a first sub-module, the first sub-module includes a plurality of first photovoltaic devices, each of the plurality of first photovoltaic devices being characterized by a first device area and having a first bandgap characteristic for providing a predetermined electrical current;

2. Interconnect the plurality of first photovoltaic devices in a serial configuration; (This process may be integrated in the above)

3. Form a second sub-module, the second sub-module includes a plurality of second photovoltaic devices, each of the plurality of second photovoltaic devices being characterized by a second device area and having a second bandgap characteristic for providing the predetermined electrical current;

4. Interconnect the plurality of second photovoltaic devices in a serial configuration; (This process may be integrated in the above)

5. Mount the first sub-module over the second sub-module.

6. Perform other steps, as desired.

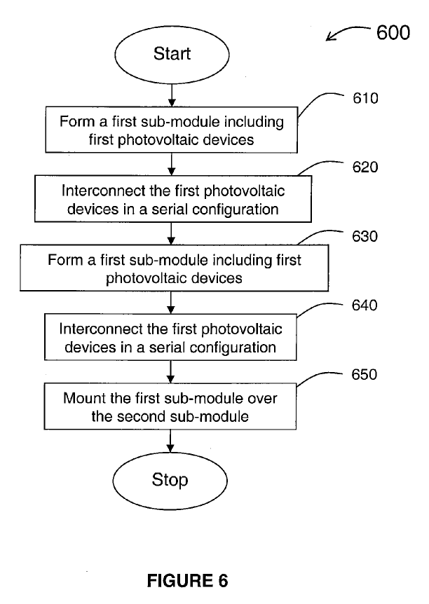

FIG. 6 is a simplified diagram of a method of matching a plurality of first photovoltaic devices to a plurality of second photovoltaic devices in forming a solar module according to an embodiment of the present invention. This diagram is merely an example, which should not unduly limit the scope of the claims herein. One of ordinary skill in the art would recognize other variations, modifications, and alternatives.

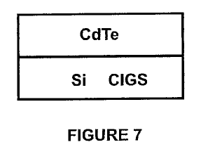

FIGS. 7, is a simplified diagram illustrating an example of photovoltaic device that can be arranged as first, second, third, and Nth devices according to a specific embodiment of the present invention. As shown, an upper cell can be made of cadmium telluride (CdTe) material that is a crystalline compound formed from cadmium and tellurium. In a specific embodiment, the CdTe has a zinc blend (cubic) crystal structure. As an example, the CdTe crystalline form a direct bandgap semiconductor. Depending upon the embodiment, the CdTe can be sandwiched with cadmium sulfide to form a pn junction photovoltaic solar cell. Additionally, the lower cell can be made of an alternative material that receives any traversing energy through the upper cell. As an example, the lower cell can be made of a suitable material such as silicon, polysilicon, CIGS, and other materials. Of course, there can be other variations, modifications, and alternatives. Of course, there can be other variations, alternatives, and modifications.

In a preferred embodiment, the upper cell can be made according to High Efficiency Photovoltaic Cell and Manufacturing Method listed under U.S. Ser. No. 61/059,253 (Attorney Docket No. 026335-002500US), commonly assigned, and hereby incorporated for all purposes. In one or more embodiments, the top cell comprises an absorber layer selected from CuInS₂, SnS, Cu(In₂Al)S₂, Cu(In₁₋ₓ), Alₓ)S₂, Cu(In, Ga)S₂, or Cu(In₁₋ₓ, Ga)S₂ or other suitable materials. In other specific embodiments, the bottom cell may comprise an absorber layer selected from CIGS, Cu₂SnS₃, FeS₂, or Ge or others.

It is also understood that the examples and embodiments described herein are for illustrative purposes only and that various modifications or changes in light thereof will be suggested to persons skilled in the art and are to be included within the spirit and purview of this application and scope of the appended claims.

1. A multi-junction solar module device, the device comprising;
a substrate member;
a plurality of first photovoltaic devices arranged in a first spatial configuration, the plurality of first photovoltaic devices numbered from 1 through N, where N is an integer greater than 1, each of the plurality of first photovoltaic devices being, characterized by a first device area and having a first bandgap characteristic;
a plurality of second photovoltaic devices arranged in a second spatial configuration, the plurality of second photovoltaic devices numbered from 1 through M, where M is an integer greater than 1, whereupon N is not equal to M, each of the second photovoltaic devices being characterized by a second device area and having a second band gap characteristic;
a first connector interconnecting the plurality of first photovoltaic devices in a serial configuration, the first connector having a first terminal end and a second terminal end;
a second connector interconnecting the plurality of second photovoltaic devices in a serial configuration; the second connector having a first terminal end and a second terminal end;
a third connector connecting the second terminal end of the first connector and the first terminal end of the second connector;
a first output node coupled to the first terminal end of the first connector;
a second output node coupled to the second terminal end of the second connector; and
whereupon N and M are selected to match a first current through the plurality of first photovoltaic devices and a second current through the plurality of second photovoltaic devices.

2. The device of claim 1 further comprising a glass cover overlying the plurality of second photovoltaic devices.

3. The device of claim 1 further comprising an EVA overlying the plurality of second photovoltaic devices.

4. The device of claim 1 further comprising an insulating material provided between the plurality of first photovoltaic devices.

5. The device of claim 1 wherein the first bandgap ranges from about 1.5 eV to about 1.9 eV.

6. The device of claim 1 wherein the second bandgap ranges from about 0.7 eV to about 1 eV.

7. The device of claim 1 further comprising a plurality of third photovoltaic devices arranged in a third spatial configuration, the plurality of third photovoltaic devices numbered from 1 through P, where P is an integer greater than 1, whereupon P is not equal to N or M, the plurality of third photovoltaic devices being coupled to the plurality of first photovoltaic devices and the plurality of second photovoltaic devices.

8. The device of claim 1 wherein each of the plurality of first photovoltaic devices comprises an absorber layer selected from CuInS₂, SnS, Cu(In₂Al)S₂, Cu(In₁₋ₓ), Alₓ)S₂, Cu(In, Ga)S², or Cu(In₁₋ₓ, Ga)S₂.

9. The device of claim 1 wherein each of the plurality of second photovoltaic devices comprises an absorber layer selected from CIGS, Cu₂SnS₃, FeS₂, or Ge.

10. The device of claim 1 wherein each of the plurality of first photovoltaic devices comprises a copper indium disulfide species as an absorber layer and each of the plurality of second photovoltaic devices comprises CIGS species as an absorber layer.

11. (canceled)

12. A multi-junction solar module device, the device comprising:
a substrate member;
a plurality of first photovoltaic devices arranged in a first spatial configuration, the plurality of first photovoltaic devices numbered from 1 through N, where N is an integer greater than 1, each of the plurality of first photovoltaic devices being characterized by a first device area and having a first bandgap characteristic;
a plurality of second photovoltaic devices arranged in a second spatial configuration, the plurality of second photovoltaic devices numbered from 1 through M, where M is an integer greater than 1, whereupon N is not equal to M, each of the second photovoltaic devices being characterized by a second device area and having a second band gap characteristic;
a first plurality of connectors interconnecting the plurality of first photovoltaic devices in a parallel configuration, the first plurality of connectors having a first terminal end and a second terminal end;
a second plurality of connectors interconnecting the plurality of second photovoltaic devices in a parallel configuration; the second plurality of connectors having, a first terminal end and a second terminal end;
a third connector connecting the second terminal end of the first plurality of connectors and the first terminal end of the second plurality of connectors;
a first output node coupled to the first terminal end of the first plurality of connectors;
a second output node coupled to the second terminal end of the second plurality of connector; and
whereupon N and M are selected to match a first total current through the plurality of first photovoltaic devices and a second total current through the plurality of second photovoltaic devices.

13. The device of claim 12 wherein each of the plurality of first photovoltaic devices comprises a serial or parallel combination of a plurality of third photovoltaic devices.

14. The device of claim 12 wherein each of the plurality of second photovoltaic devices comprises a serial or parallel combination of a plurality of fourth photovoltaic devices.

15. A method for making a multi-junction solar module device, the method comprising:
forming a first sub-module, the first sub-module includes a plurality of first photovoltaic devices, each of the plurality of first photovoltaic devices being characterized by a first device area and having a first bandgap characteristic for providing a predetermined electrical current;
interconnecting the plurality of first photovoltaic devices in a serial configuration;
forming a second sub-module, the second sub-module includes a plurality of second photovoltaic devices, each of the plurality of second photovoltaic devices being characterized by a second device area and having a second bandgap characteristic for providing the predetermined electrical current;
interconnecting the plurality of second photovoltaic devices in a serial configuration;
mounting the first sub-module over the second sub-module.
